(19) United States
(12) Patent Application Publication
(10) Pub. No.: US 2026/0150622 A1
(43) Pub. Date: May 28, 2026

(54) SUBSTRATE SUPPORT APPARATUS AND OPERATION METHOD OF THE SAME

(71) Applicant: Samsung Electronics Co., Ltd., Suwon-si (KR)

(72) Inventors: SUNGHO KANG, Suwon-si (KR); HYUNJOO LEE, Suwon-si (KR)

(21) Appl. No.: 19/251,553

(22) Filed: Jun. 26, 2025

(30) Foreign Application Priority Data
Nov. 22, 2024 (KR) 10-2024-0168457

(51) Int. Cl. H01L 21/687

(52) U.S. Cl. CPC H10P 72/7612

(57) ABSTRACT

The present disclosure relates to a substrate support apparatus and an operation method of the same. In addition, the present disclosure is related to a method of manufacturing a semiconductor device using the operation method of the substrate support apparatus. A substrate support apparatus according to embodiment includes a chuck configured to mount a substrate thereon, and a lift pin that passes through the chuck. The lift pin has a support portion that is configured to support a lower surface of the substrate. The support portion of the lift pin is spaced apart from a center of the lift pin in a plan view.

### CROSS-REFERENCE TO RELATED APPLICATION

This application claims priority to and the benefit of Korean Patent Application No. 10-2024-0168457 filed in the Korean Intellectual Property Office on November, 22, 2024, the entire contents of which are incorporated herein by reference.

### BACKGROUND

### (a) Field

The present disclosure relates to a substrate support apparatus and an operation method of the same. In addition, the present disclosure is related to a method of manufacturing a semiconductor device using the operation method of the substrate support apparatus.

### (b) Description of the Related Art

A semiconductor manufacturing apparatus may include a substrate support apparatus that supports a substrate in a chamber in which a semiconductor manufacturing process is performed. The substrate support apparatus may include a chuck on which a substrate is mounted and a lift pin supporting at least a portion of the substrate and moving the substrate in a vertical direction.

A semiconductor manufacturing process may have a series of process steps to be performed to produce a device. The semiconductor manufacturing process may be repeated to produce a plurality of devices. In the series of process steps, lift pins may support and contact predetermined positions of a substrate, and the predetermined positions may be repeatedly subject to the contact and/or similar types of mechanical contact. By the repeated contact of the lift pins and/or others, problems such as contamination or damage of the substrate may be induced.

### SUMMARY

One of the aspects of the present disclosure attempts to provide a substrate support apparatus and an operation method of the same.

A substrate support apparatus according to an embodiment includes a chuck configured to mount a substrate thereon, and a lift pin that passes through the chuck. The lift pin has a support portion that is configured to support a lower surface of the substrate. The support portion of the lift pin is spaced apart from a center of the lift pin in a plan view.

A substrate support apparatus according to an embodiment includes a chuck configured to mount a substrate thereon, and a lift pin that passes through the chuck and configured to support the substrate. The lift pin includes a support portion configured to contact the substrate, and the support portion is at an upper portion of the lift pin. The lift pin is configured to be rotated and support the substrate in a first support position or a second support position different from each other in a plan view.

An operation method of a substrate support apparatus according to an embodiment includes providing the substrate support apparatus including a lift pin and a chuck, and a horizontal position of a support portion of the lift pin is a first support position. The operation method further includes adjusting the lift pin to change the horizontal position of the support portion of the lift pin from the first support position to a second support position, and the second support position is different from the first support position. The operation method further includes mounting a substrate on the chuck, while the horizontal position of the support portion of the lift pin is in the second support position, and separating the substrate from the chuck while the horizontal position of the support portion of the lift pin is in the second support position.

A method for manufacturing a semiconductor device according to an embodiment includes processing a substrate that is supported by a substrate support apparatus, according to an embodiment includes supporting the substrate using the substrate support apparatus, and processing the substrate as it supported by the substrate support apparatus. The substrate support apparatus includes a chuck configured to secure the substrate, and a lift pin that passes through the chuck and configured to support a lower surface of the substrate. The supporting operation is performed such that a support portion of the lift pin supports the lower surface of the substrate. The support portion of the lift pin is spaced apart from a center of the lift pin in a plan view.

The substrate support apparatus may further include an actuator. The supporting operation may be performed such that the substrate is in contact with the chuck after a horizontal position of the support portion of the lift pin is changed from a first support position to a second support position by using the actuator.

The lift pin may be rotatable, and the method may further include rotating the lift pin so that a horizontal position of the support portion of the lift pin changes from a first support position to a second support position.

The method may further include adjusting a horizontal position of the support portion of the lift pin to a position between the center of the lift pin and an edge of the substrate or the chuck in a plan view.

The method may further include adjusting the lift pin to change a horizontal position of the support portion of the lift pin from a first contact point on the substrate to a second contact point on the substrate.

The lift pin may include a main body and a protruding portion that extends from an upper portion of the main body. With respect to a vertical cross section, the protruding portion may have an asymmetrical shape with respect to a vertical line passing through the center of the main body, and the support portion of the lift pin may form a top end of the protruding portion.

The main body and the protruding portion may constitute a continuous body.

The lift pin may include a main body and an upper body portion that locates at an upper portion of the main body, and the support portion of the lift pin may locate at a portion of the upper body portion.

The upper body portion may include a protruding part that protrudes in a direction away from the main body and may have an area of footprint less than an area of horizontal cross-section of the main body, and the protruding part may locate at an outside of the main body in a plan view.

In a direction parallel to an upper surface of the chuck, a width of the upper body portion may be greater than a maximum width of the main body in a cross-sectional view.

The upper body portion may be removable or detachable from the main body.

The upper body portion may be formed of the same material as that of the main body.

A method for manufacturing a semiconductor device according to an embodiment may include processing a substrate that is supported by a substrate support apparatus, according to an embodiment includes supporting the substrate using the substrate support apparatus, and processing the substrate as it supported by the substrate support apparatus. The substrate support apparatus includes a chuck configured to secure the substrate, and a lift pin that passes through the chuck and configured to support the substrate. The lift pin includes a support portion configured to support the substrate, and the support portion extends from an upper portion of the lift pin, and the lift pin is rotatable and configured to support the substrate in a first support position and a second support position different from each other in a plan view.

The substrate support apparatus may further include an actuator configured to rotate the lift pin to change a horizontal position of the support portion of the lift pin, and the support portion of the lift pin may be spaced apart from a center of the lift pin in a plan view.

The support portion of the lift pin may be configured to support a lower surface of the substrate while the support portion of the lift pin is between a center of the lift pin and an edge of the chuck in a plan view.

The lift pin may be configured to be adjusted thereby changing a horizontal position of the support portion of the lift pin into the first support position, and, in the first support position, a mechanical contact with the substrate has occurred in a preceding process.

According to embodiment, by changing a horizontal position of a support portion of a lift pin that supports a substrate, contamination or damage of the substrate due to the lift pin may be minimized. Thereby, a defect of the substrate may be reduced and performance and productivity of a semiconductor device that includes the substrate or is formed by using the substrate may be enhanced. By changing a shape or a structure of the lift pin without changing a structure of a chuck or a semiconductor manufacturing apparatus, the horizontal position of the support portion of the lift pin may be easily changed or controlled.

### BRIEF DESCRIPTION OF THE DRAWINGS

FIG. 1 is a perspective view that illustrates a substrate support apparatus according to an embodiment.

FIG. 2 is a cross-sectional view that conceptually illustrates the substrate support apparatus illustrated in FIG. 1.

FIG. 3 is an enlarged cross-sectional view that illustrates a portion B in FIG. 2.

FIG. 4 a block diagram that illustrates a driver and a controller included in the substrate support apparatus illustrated in FIG. 1.

FIG. 5 illustrates an example of a semiconductor manufacturing apparatus that includes the substrate support apparatus illustrated in FIG. 1.

FIG. 6 illustrates an example of a semiconductor manufacturing apparatus that includes the substrate support apparatus illustrated in FIG. 1.

FIG. 7A and FIG. 7B conceptually illustrate an operation method of a substrate support apparatus according to an embodiment.

FIG. 8 illustrates an example of changing a planar position of a support portion of a lift pin in an operation method of a substrate support apparatus according to an embodiment.

FIG. 9 illustrates an example of changing a planar position of a support portion of a lift pin in an operation method of a substrate support apparatus according to an embodiment.

FIG. 10 conceptually illustrates an operation method of a plurality of substrate support apparatuses included in a plurality of semiconductor manufacturing apparatuses.

FIG. 11 is a cross-sectional view that illustrates a portion of a substrate support apparatus according to an embodiment.

FIG. 12 is a cross-sectional view that illustrates a portion of a substrate support apparatus according to an embodiment.

FIG. 13 illustrates a substrate support operation according to an embodiment.

### DETAILED DESCRIPTION

Embodiments of the present disclosure will be described in detail hereinafter with reference to the accompanying drawings. Accordingly, those skilled in the art to which the present disclosure pertains may easily implement the present disclosure. The present disclosure may be implemented in various different forms, and the invention is not limited to the embodiments provided herein.

Throughout the specification, like features and elements have been identified by the same or similar reference numerals and/or letters, and duplicate descriptions may be omitted for the purpose of simplicity and clarity.

Further, since sizes and thicknesses of portions, regions, members, units, layers, films, or the like illustrated in the accompanying drawings may be arbitrarily illustrated for better understanding and convenience of explanation, the present invention is not limited to the illustrated sizes and thicknesses. In the drawings, thicknesses of portions, regions, members, units, layers, films, or the like may be enlarged or exaggerated for convenience of explanation and/or simple illustration.

It will be understood that when a component such as a layer, film, region, or substrate is referred to as being “on” another component, it may be directly on other component or an intervening component may also be present. In contrast, when a component is referred to as being “directly on” or “in contact with” another component, there is no intervening component present (at least at the point of contact).

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Further, throughout the specification, the phrases “on a plane”, “in a plane”, “on a plan view”, “in a plan view” and “top down view” may be used when describing a portion as viewed from above or top, and the phrases “on a cross-section” and “in a cross-sectional view” may be used when describing a portion as viewed from a side unless context indicates otherwise.

Items described in the singular herein may be provided in plural, as can be seen, for example, in the drawings. Thus, the description of a single item that is provided in plural should be understood to be applicable to the remaining plurality of items unless context indicates otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. However, it should be appreciated that the spatially relative terms are intended to encompass different orientations of the device in use or operation in addition to the orientation depicted in the figures. For example, being “above” a particular element will be understood to not require a particular orientation with respect to the direction of gravity.

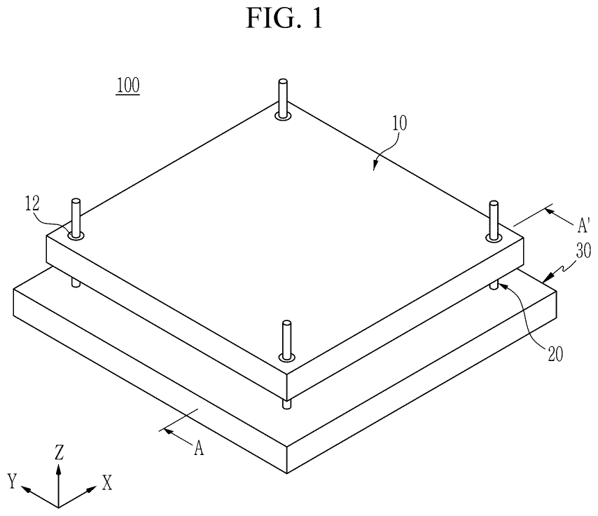

Hereinafter, referring to FIG. 1 to FIG. 10, a substrate support apparatus according to embodiments and an operation method of the same will be described in detail.

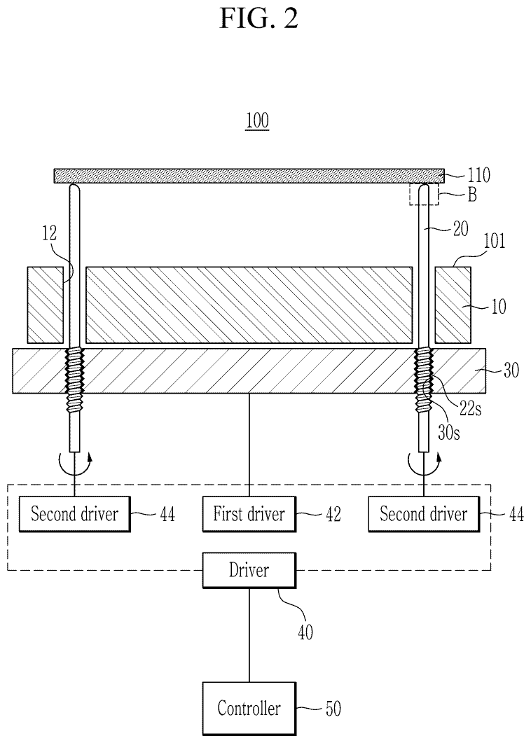

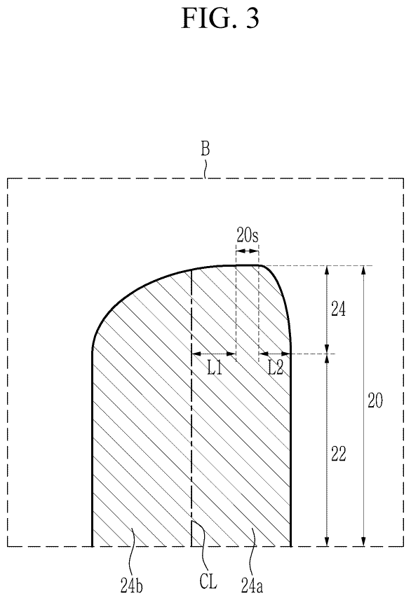

FIG. 1 is a perspective view that illustrates a substrate support apparatus 100 according to an embodiment. FIG. 2 is a cross-sectional view that illustrates the substrate support apparatus 100 illustrated in FIG. 1. FIG. 2 illustrates a state, in which a substrate 110 is disposed on the substrate support apparatus 100, taken along a line A-A′ in FIG. 1. FIG. 2 conceptually illustrates a driver 40 and a controller 50. FIG. 3 is an enlarged cross-sectional view that illustrates a portion B in FIG. 2.

Referring to FIG. 1 to FIG. 3, a substrate support apparatus 100 according to an embodiment may include a chuck 10 on which a substrate 110 is mounted or disposed, and a lift pin 20 that passes through the chuck 10 and is configured to support the substrate 110. For example, the substrate support apparatus 100 may be a part of a semiconductor manufacturing apparatus used in, e.g., a substrate processing, substrate testing, packaging and so on.

In an embodiment, the chuck 10 may be an electro-static chuck that is in close contact with and fixes (or secures) the substrate 110 using an electrostatic force. The chuck 10 may have any of various structures. The chuck 10 may be of a type other than an electrostatic chuck. For example, the chuck 10 may be a vacuum chuck.

The chuck 10 may have a plate shape having an area greater than an area of the substrate 110 in a plan view and having a predetermined thickness in a vertical direction (a Z-axis direction in the drawings). In FIG. 1, it is illustrated as an example that the chuck 10 has a rectangular planar shape. However, the embodiments are not limited thereto, and the chuck 10 may have any of various planar shapes (e.g., a circular planar shape or the like). A first surface 101 (e.g., an upper surface) of the chuck 10 may be a mounting surface on which the substrate 110 is mounted or disposed.

In the specification, the vertical direction (the Z-axis direction in the drawings) may be a direction perpendicular to the substrate 110 (or the first surface 101 of the chuck 10) and a support direction of the substrate 110. The support direction may be a direction in which the lift pins 20 support.

The chuck 10 may include a pin hole 12 that passes through the chuck 10. In the pin hole 12, the lift pin 20 may be disposed and extend upwardly toward the substrate 110. For example, the pin hole 12 may provide a space in which the lift pin 20 moves in the vertical direction (the Z-axis direction in the drawings). In the drawings, it is illustrated as an example that a plurality of pin holes 12 are disposed near corner portions of the chuck 10, respectively. However, the embodiments are not limited thereto, and a number, a position, or the like of the pin hole 12 may be variously modified.

The substrate 110 that is disposed on the chuck 10 may be a base substrate, such as a semiconductor substrate, an insulative substrate, a metal substrate or the like, or may be a substrate structure in which a metal layer, an insulation layer, a semiconductor layer or the like is disposed on the base substrate. In an embodiment, the substrate 110 may include or be formed of a glass substrate (e.g., a quartz glass substrate). For example, the substrate 110 may be a photomask used in an exposure operation of a photolithography process or a base substrate configured to form (or configured to be a part of) the photomask. However, the embodiments are not limited thereto, and various modified embodiments are possible.

The lift pin 20 may pass through the pin hole 12 of the chuck 10 and move in the vertical direction (the Z-axis direction in the drawings). By adjusting a position of the lift pin 20 in the vertical direction, an upper portion of the lift pin 20 may protrude beyond the chuck 10, or the upper portion of the lift pin 20 may be disposed within the chuck 10. For example, the lift pin 20 may move in the vertical direction between a lower position and an upper position. In the lower position, the upper portion of the lift pin 20 may be disposed at the same level as or lower than the first surface 101 of the chuck 10. In the upper position, the upper portion of the lift pin 20 may be disposed higher than the first surface 101 of the chuck 10. In an embodiment, the lift pin 20 may be rotated by a driver 40 (e.g., a second driver 44) configured to rotate the lift pin 20. This will be described later in more detail.

In an embodiment, the lift pin 20 may support at least a portion of the substrate 110. For example, at least a portion of the upper portion of the lift pin 20 may support a lower surface of the substrate 110. For example, a support portion 20s that is disposed at (e.g., in) the upper portion of the lift pin 20 may be in contact with the lower surface of the substrate 110 and may support the substrate 110. The support portion 20s of the lift pin 20 may be an uppermost portion of the lift pin 20 that is adjacent to or is in contact with the substrate 110 in the vertical direction (the Z-axis direction in the drawings). The support portion 20s of the lift pin 20 may be referred to as an uppermost portion, a substrate-adjacent portion, a substrate-contact portion, or the like.

In an embodiment, the lift pin 20 may include a main body 22, and a protruding portion (or end portion) 24 that is disposed at the upper portion of the main body 22. The support portion 20s of the lift pin 20 may be a portion (e.g., an uppermost portion) of the protruding portion 24.

The main body 22 may extend in the vertical direction (the Z-axis direction in the drawings) to pass through the pin hole 12. The main body 22 may have substantially the same area except for a portion having a thread 22s and/or a portion configured to be connected to the driver 40 (e.g., second driver 44). For example, an area of horizontal cross-section of the lift pin 20 may be substantially constant across most of the lift pin 20, but it may differ in the upper and lower end portions of the lift pin 20 and in the middle portion of the main body 22. The main body 22 may have the thread 22s in the middle portion. The term ‘footprint’ of an element may be the area of a vertical projection of the element onto a horizontal plane (or horizontal planar surface, such as that of the chuck 10 or substrate 110) to describe the horizontal area occupied by the element.

For example, the main body 22 may have a column shape. In the drawings, it is illustrated as an example that the main body 22 has a circular cylinder shape. However, the embodiments are not limited thereto, and a shape of the main body 22 may be variously modified.

A driver 40 configured to move the lift pin 20 in the vertical direction and/or rotate the lift pin 20 may be connected to the main body 22. In some embodiments, the main body 22 may include a portion configured to move the lift pin 20 in the vertical direction and/or rotate the lift pin 20. This will be described later together with the driver 40.

The protruding portion 24 may be disposed at the upper portion of the main body 22. The protruding portion 24 may be tapered with respect to the vertical direction such that the width and/or horizontal area of the protruding portion 24 decreases in the vertical direction. The horizontal cross sectional area of the protruding portion 24 may gradually decrease with respect to distance away from main body 22 (as it goes toward the support portion 20s that is adjacent to (or in contact with) the lower surface of the substrate 110). For example, an upper surface of the protruding portion 24 may be a rounded surface or a curved surface, and the support portion 20s may be disposed at an uppermost portion of the upper surface of the protruding portion 24.

The support portion 20s may be offset from the center axis of the main body 22. The center axis may extend along the lengthwise direction of the lift pin 20. In an embodiment, in a plan view, the support portion 20s of the lift pin 20 may be spaced apart from a center of the lift pin 20. For example, in a plan view, the support portion 20s of the lift pin 20 may be spaced apart from a center line CL of the main body 22 extending in the vertical direction (the Z-axis direction in the drawings). For example, the protruding portion 24 may have an asymmetrical shape based on (with respect to) the center line CL of the main body 22 in a cross-sectional view. For example, the upper surface of the protruding portion 24 of the rounded surface or the curved surface may have an asymmetrical shape based on the center line CL of the main body 22 in a cross-sectional view. The protruding portion 24 may have an asymmetrical shape with respect to a vertical plane extending along the center line CL of the main body 22. For example, a first portion 24a of the protruding portion 24 that is disposed at one side (a right side in the drawings) of the center line CL of the main body 22 may protrude to be higher than a second portion 24b of the protruding portion 24 that is disposed at the other side (a left side in the drawings) of the center line CL of the main body 22. The support portion 20s may be (or disposed in) at least a portion of the first portion 24a of the protruding portion 24 that protrudes to be higher than the second portion 24b of the protruding portion 24.

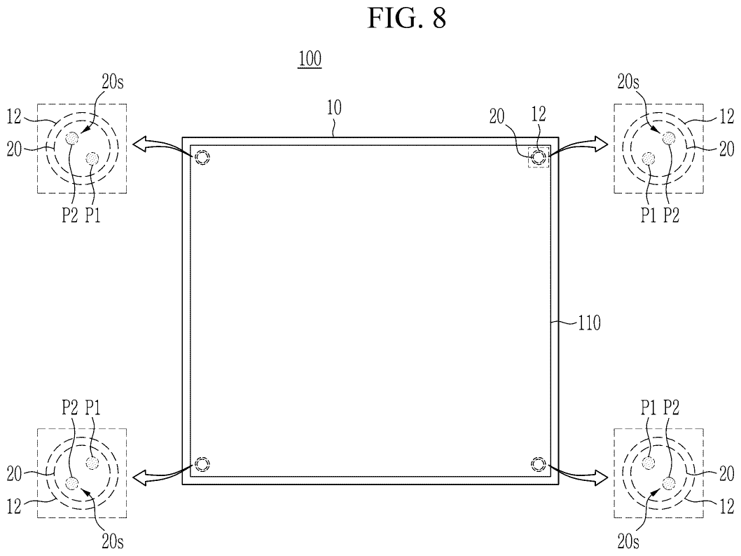

The lift pin 20 may be rotated by the driver 40 (e.g., the second driver 44). For example, the lift pin 20 may rotate so that a planar position (or horizontal position, e.g., a position on a horizontal plane) of the support portion 20s of the lift pin 20 changes from a first support position P1 (refer to FIG. 8) to a second support position P2 (refer to FIG. 8). Thereby, in a plan view, the support portion 20s of the lift pin 20 may support the lower surface of the substrate 110 in a plurality of support positions (e.g., the first support position P1 and the second support position P2).

As described above, an area (or an area of horizontal cross-section) of the protruding portion 24 may gradually decrease with respect to distance away from the main body 22. The protruding portion 24 may be disposed to overlap the main body 22 in a plan view and may have an area (or an area of footprint) which is the same as or smaller than an area (or an area of horizontal cross-section) of the main body 22. The shape of the lift pin 20 including the support portion 20s spaced apart from the center of the lift pin 20 may be obtained by processing (e.g., grinding, cutting, and other similar operations) an upper portion of the lift pin 20. In some embodiments, the shape of the lift pin 20 may be obtained by combining and/or rearranging (e.g., modifying, adjusting, repositioning, replacing and so on) of a plurality of sub-components.

In an embodiment, the support portion 20s of the lift pin 20 may be disposed within the main body 22 in a plan view. For example, in a plan view, a first distance L1 may be greater than a second distance L2. The first distance L1 may be a shortest distance between the support portion 20s of the lift pin 20 and the center of the lift pin 20 (e.g., the center line CL of the main body 22) in a horizontal plane. The second distance L2 may be a shortest distance between the support portion 20s of the lift pin 20 and an edge of the lift pin 20 (in particular, an edge of the main body 22) in the horizontal plane. Thereby, by the rotation of the lift pin 20, the planar position of the support portion 20s of the lift pin 20 may be easily changed. However, the embodiment is not limited thereto. In some embodiments, the first distance L1 between the support portion 20s of the lift pin 20 and the center of the lift pin 20 may be the same as or less than the second distance L2 between the support portion 20s of the lift pin 20 and the edge of the lift pin 20.

In an embodiment, an area (an area of footprint) of the support portion 20s of the lift pin 20 may be less than an area (an area of horizontal cross-section) of the main body 22, and such small area (an area of footprint) of a portion of the lift pin 20 that is adjacent to (or in contact with) the lower surface of the substrate 110 may help reduce damage or contamination of the substrate 110 that may be induced in the support position of the lift pin 20. The area of horizontal cross-section of the main body 22 may be a maximum area of horizontal cross-section of the main body 22. An area of the support portion 20s may refer to an area of the uppermost portion of the lift pin 20 or an area of the portion that is adjacent to (or in contact with) the lower surface of the substrate 110.

The area of the footprint of the support portion 20s may have a value in the range of 10% to 30% of the area of the footprint of the main body 22, however the invention is not limited thereto. For example, the area of the footprint of the support portion 20s may be 10% of the area of the footprint of the main body 22 or more thereby helping stably support the substrate 110, and the area of the footprint of the support portion 20s may be 30% of the area of the footprint of the main body 22 or less thereby helping effectively reduce the damage or the contamination on the substrate 110. However, the embodiments are not limited thereto. In some embodiments, the area of the footprint of the support portion 20s may be less than 10% or greater than 30% of the area of the footprint of the main body 22.

By rotating the lift pin 20 clockwise or counterclockwise in a plan view, the planar position of the support portion 20s may be changed. The rotation of the lift pin 20 may be performed using its center axis extending along the lengthwise direction of the lift pin 20 as the axis of rotation. During the rotation, the planar position of the support portion 20s may follow a trajectory, and the maximum distance between two points on the trajectory may be a maximum position deviation of the support portion 20s. In some embodiments, the maximum position deviation may be in a range of 0.2 mm to 3 mm. For reference, the maximum position deviation of the support portion 20s by the rotation of the lift pin 20 may be twice the first distance L1 between the support portion 20s of the lift pin 20 and the center of the lift pin 20. When the maximum position deviation of the support portion 20 s by the rotation of the lift pin 20 is 0.2 mm or more, the planar position of the support portion 20s of the lift pin 20 may be sufficiently changed by the rotation of the lift pin 20. In an embodiment, the maximum position deviation of the support portion 20 s by the rotation of the lift pin 20 may be 3 mm or less, such that a problem in which the support portion 20s of the lift pin 20 interferes with or contaminates a secured area of the substrate 110 may be sufficiently reduced and any defect induced therefrom may be suppressed. The secured area of the substrate 110 may be an inner portion of the substrate 110 in a plan view and may be secured to the chuck 10 by the electrostatic force. However, the maximum position deviation is not limited thereto, and the maximum position deviation of the support portion 20s by the rotation of the lift pin 20 may be less than 0.2 mm or greater than 3 mm.

In an embodiment, the lift pin 20 that includes the main body 22 and the protruding portion 24 may be a single continuous body to have an integral structure. Through processing the upper portion of the lift pin 20, the protruding portion 24 (or the support portion 20s) may be formed to have the offset configuration as described above. However, the embodiments are not limited thereto, and the protruding portion 24 may be separately formed from (and/or be coupled to) the main body 22 and be fixed to the main body 22 to form the lift pin 20. The protruding portion 24 may be removably or detachably fixed (coupled) to the main body 22, or may be fixed to the main body 22 in a non-separable or non-detachable manner. Other various modified embodiments are possible.

In an embodiment, the lift pin 20 (in particular, the main body 22 and/or the protruding portion 24) may include or be formed of any of various materials, such as metal, a carbon-based material, a fiber-reinforced resin, or the like.

In an embodiment, a plurality of lift pins 20 may be movably fixed to a single fixing member 30. The fixing member 30 may be a structure or a member configured to integrate the plurality of lift pins 20 such that the planar positions of the plurality of lift pins 20, relative to each other, may remain constant. In the drawings, it is illustrated as an example that the fixing member 30 has a plate shape, but a shape or a structure of the fixing member 30 may be variously modified. By the fixing member 30, a structure of the substrate support apparatus 100 that includes the plurality of lift pins 20 may be simplified and the plurality of lift pins 20 may easily move (e.g., move in the vertical direction). However, the embodiment is not limited thereto. In some embodiments, the plurality of lift pins 20 may be individually provided and individually, independently or separately move (e.g., move in the vertical direction). Other various modified embodiments are possible.

The driver 40 may be an actuator or a combination of actuators such as linear actuators, rotary actuators and so on. In an embodiment, the driver 40 may be configured to move the lift pin 20 in the vertical direction and rotate the lift pin 20. In an embodiment, the driver 40 may include a first driver 42 configured to move the lift pin 20 in the vertical direction to change a vertical position of the lift pin 20, and a second driver 44 configured to rotate the lift pin 20 to change a planar position of the support portion 20s. The first driver 42 may be referred to as a vertical driver, a vertical actuator or a vertical-position changing portion, and the second driver 44 be referred to as a rotation driver, a rotation actuator or a planar-position changing portion.

The first driver 42 may be configured to change the vertical position of the lift pin 20 in the vertical direction (the Z-axis direction in the drawings). The vertical position of the lift pin 20 may be a relative vertical position with respect to the chuck 10 in the vertical direction. The first driver 42 may move the chuck 10 and/or the lift pin 20 in the vertical direction. In FIG. 2, it is illustrated as an example that the first driver 42 is connected to the fixing member 30 where the plurality of lift pins 20 are connected and to move the fixing member 30 in the vertical direction. However, the embodiment is not limited thereto. In some embodiments, the first driver 42 may be configured to be connected to the lift pin 20 and move the lift pin 20 in the vertical direction, or the first driver 42 may be configured to be connected to the chuck 10 and move the chuck 10 in the vertical direction. For the first driver 42 configured to change the vertical position of the lift pin 20, any of various structures or types may be applied. The first driver 42 may be or include a linear actuator (e.g., electric linear actuators, pneumatic linear actuators, hydraulic linear actuators and so on).

The second driver 44 may be or include a rotary actuator (e.g., electric rotary actuators, pneumatic rotary actuators, hydraulic rotary actuators and so on) which rotates the lift pin 20 and may change the planar position of the support portion 20s in a plane (an XY plane in the drawings). Since the support portion 20s is eccentric (or offset), the planar position of the support portion 20s may be easily changed by the rotation of the lift pin 20. For the second driver 44 configured to rotate the lift pin 20, a motor (e.g., servomotor) that generates a rotation movement or the like may be applied. However, the embodiments are not limited thereto, and a structure or a type of the second driver 44 may be variously modified.

In an embodiment, the fixing member 30 may have a through hole configured to provide a space in which the lift pin 20 moves, and an inner surface of the through hole of the fixing member 30 may be provided with a thread 30s. An outer surface of the main body 22 of the lift pin 20 may be provided with a thread 22s configured to be engaged to the thread 30s of the fixing member 30. Accordingly, the lift pin 20 may be stably rotated by a simple structure and the planar position of the support portion 20s of the lift pin 20 may be changed. However, the embodiments are not limited thereto, and any of various structures, in which the lift pin 20 is rotatable, may be applied.

In an embodiment, it is described as an example that the driver 40 includes the first driver 42 and the second driver 44 separately. Thereby, the change in the vertical position of the lift pin 20 by the first driver 42 and the change in the planar position of the lift pin 20 by the second driver 44 may be performed separately or independently from each other, thereby preventing unwanted interference. However, the embodiment is not limited thereto. For example, the driver 40 may be configured to adjust the vertical position of the lift pin 20 and the planar position of the lift pin 20 together or simultaneously. Besides, the driver 40 may have any of various structures, types, or the like configured to adjust the vertical position of the lift pin 20 and the planar position of the lift pin 20.

A controller 50 may control the driver 40 and control the vertical position of the lift pin 20 and the planar position of the lift pin 20.

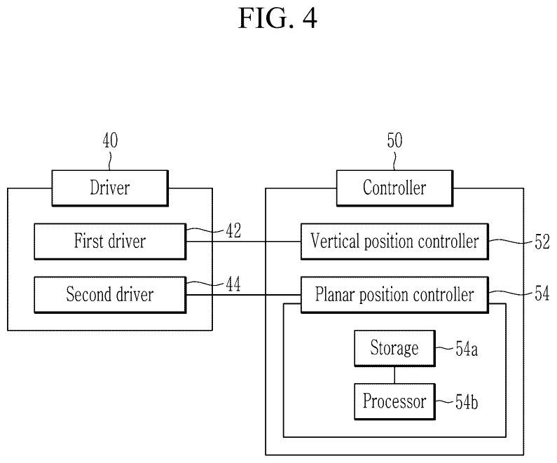

Referring to FIG. 4 together with FIG. 1 to FIG. 3, the driver 40 and the controller 50 included in the substrate support apparatus 100 will be described in more detail. FIG. 4 a block diagram that illustrates the driver 40 and the controller 50 included in the substrate support apparatus 100 illustrated in FIG. 1. FIG. 4 mainly illustrates a planar position controller 54 of the controller 50.

Referring to FIG. 1 to FIG. 4, in an embodiment, the controller 50 may include a vertical position controller 52 and a planar position controller 54.

The vertical position controller 52 may control the driver 40 (e.g., the first driver 42) and control the vertical movement of the lift pin 20. Thereby, the vertical position of the lift pin 20 may be controlled.

The planar position controller 54 may control the driver 40 (e.g., the second driver 44) and control the rotation of the lift pin 20. Thereby, the planar position of the lift pin 20 may be controlled. For example, the planar position controller 54 may include a storage 54a and a processor 54b.

For example, the controller 50 may be a semiconductor device including processor 54b (e.g., one or more of a DSP, an FPGA, a CPU, a GPU, a microprocessor, etc.), and the controller 50 may include the vertical position controller 52 and the planar position controller 54 as separate processors (forming processor 54b) or as functional components of the processor 54b (e.g., processor configured by software).

The storage 54a may store support position information. For example, the stored support position information may include the history of the substrate 110. The history may include which areas and/or locations of the substrate 110 have had mechanical contact with a specific production apparatus (or apparatuses), how many mechanical contacts were made in such areas of the substrate 110, and so on.

In an embodiment, the support position information may further include information on the semiconductor manufacturing apparatus (or the substrate support apparatus 100). The support position information may be as to how many times the support portion 20s has been in contact with the substrate 110 (and/or other substrates) in each specific planar position. For example, the store support position information may include each support position of the substrate 110 corresponding to each support position of the support portion 20s of the lift pin 20 that is adjacent to (or in contact with) the substrate 110.

In addition, the support position information may further include information on target position information. The processor 54b may generate the target position information (non-overlapping position information) through using the history of the substrate in a preceding process (or preceding processes) included in the support position information, and transmit the non-overlapping position information to the storage 54a and the driver 40 (e.g., the second driver 44). The non-overlapping position information may include information on a position or positions where the support portion 20s of the lift pin 20 is either not positioned or less positioned in the preceding process(es). The storage 54a may receive the non-overlapping position information and store the non-overlapping position information. The stored non-overlapping position information may be used as at least a part of a support position information in a succeeding process. The driver 40 (e.g., the second driver 44) may receive the non-overlapping position information and may rotate the lift pin 20 to change the planar position of the support portion 20s of the lift pin 20 to the non-overlapping position in the succeeding process of the substrate 110 in the semiconductor manufacturing apparatus or in other semiconductor manufacturing apparatuses.

Though it is described as an example that the controller 50 is configured to have the planar position controller 54 and the vertical position controller 52 as individual components, the invention is not limited thereto. For example, it is described as an example that the planar position controller 54 configured to control the planar position of the support portion 20s of the lift pin 20 or the storage 54a, and the processor 54b included in the planar position controller 54 are separately included, but the embodiments are not limited thereto. For example, other components than the controller 50 (and/or its sub-components) may perform the functions of the controller 50 (and/or the sub-components, e.g., the storage 54a and the processor 54b). In some embodiments, a controller included in the substrate support apparatus 100 or a semiconductor manufacturing apparatus that includes the substrate support apparatus 100 may perform at least a part of function of the planar position controller 54 or the storage 54a and the processor 54b included in the planar position controller 54. For example, the support position information of the substrate 110 may be stored in other components of the semiconductor manufacturing apparatus (or the substrate support apparatus 100) than the storage 54a of the controller 50. For example, in a storage for lot (batch of a plurality of substrates) information or in a production maintenance system the support position information of the substrate 110 may be stored.

It is described as an example that the storage 54a receives the non-overlapping position information from the processor 54b and stores the non-overlapping position information, and the stored non-overlapping position information is used as the support position information in the succeeding process. However, the embodiment is not limited thereto. In some embodiments, the substrate support apparatus 100 or the semiconductor manufacturing apparatus that includes the substrate support apparatus 100 may further include a sensor that detects the support position of the substrate 110. In this instance, the storage 54a may receive the support position detected by the sensor and store the support position as at least a part of the support position information. The non-overlapping position information generated in the processor 54b may be stored in the storage 54a or may not be stored in the storage 54a. In some embodiments, the storage 54a may be omitted from the controller 50.

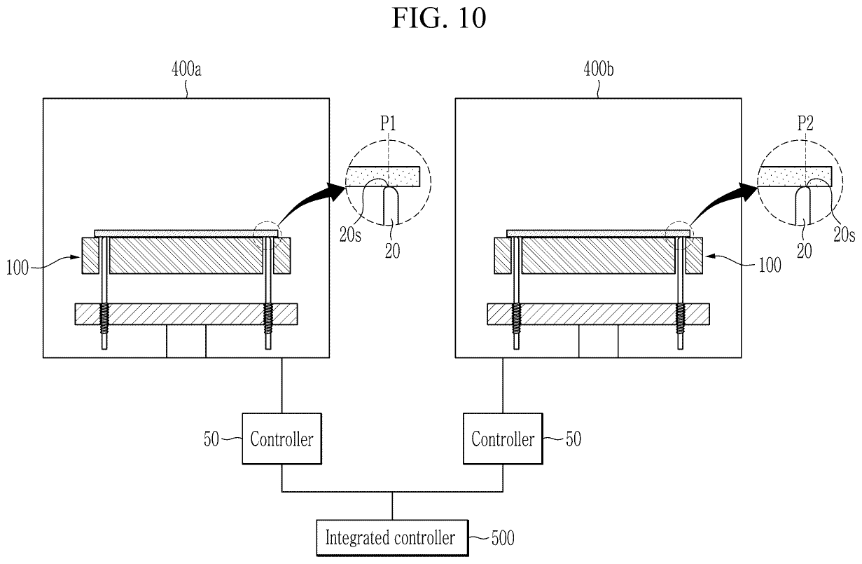

For a clear understanding and simple illustration, it is described as an example that the controller 50 controls one substrate support apparatus 100, but the invention is not limited thereto. The controller 50 may be an independent element from the semiconductor manufacturing apparatus. The controller 50 may control a plurality of substrate support apparatuses 100 that are included in a plurality of semiconductor manufacturing apparatuses, or may control a plurality of semiconductor manufacturing apparatuses. The controller 50 may be an integrated controller. The integrated controller may control a plurality of controllers 50 that control a plurality of substrate support apparatuses 100. The plurality of controllers 50 may be included in a plurality of semiconductor manufacturing apparatuses, respectively. This will be described later in more detail with reference to FIG. 10.

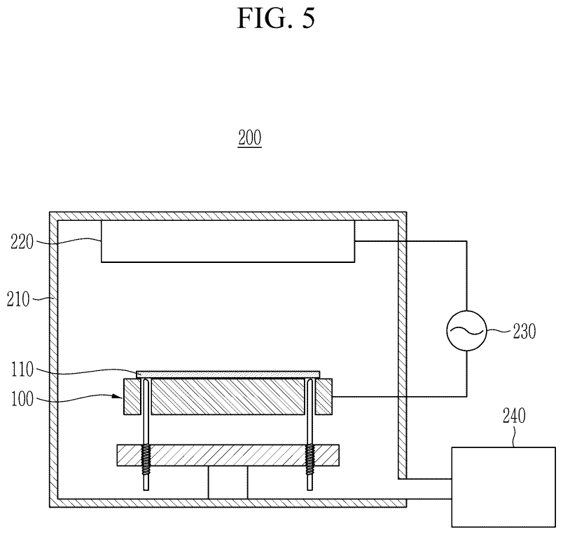

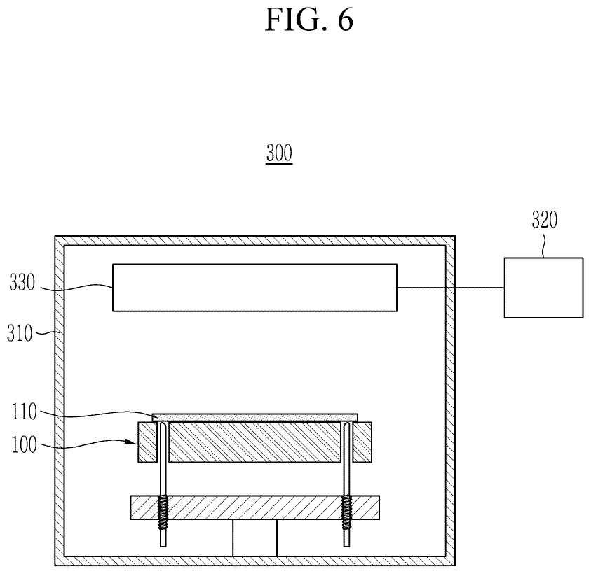

The substrate support apparatus 100 may be included in a semiconductor manufacturing apparatus. Examples of semiconductor manufacturing apparatuses, each including the substrate support apparatus 100, will be described with reference to FIG. 5 and FIG. 6. In FIG. 5 and FIG. 6, the driver 40 and the controller 50 of the substrate support apparatus 100 are omitted and the substrate support apparatus 100 is schematically illustrated.

FIG. 5 illustrates an example of a semiconductor manufacturing apparatus 200 that includes the substrate support apparatus 100 illustrated in FIG. 1.

Referring to FIG. 5, a semiconductor manufacturing apparatus 200 according to an embodiment may be a dry etching apparatus, for example, a plasma etching apparatus. For example, the semiconductor manufacturing apparatus 200 may include a chamber 210, a shower head 220, a power supply 230, an exhaust pump 240, and a substrate support apparatus 100.

The chamber 210 may provide a space in which the substrate support apparatus 100 is disposed and plasma is generated. The shower head 220 may be disposed above the substrate support apparatus 100 and provide a reaction gas. The shower head 220 may be an electrode configured to generate plasma. For example, the shower head 220 and a chuck of the substrate support apparatus 100 may be connected to the power supply 230 to generate the plasma. The exhaust pump 240 may be connected to a lower portion of the chamber 210. The space of the chamber 210 may be exhausted to maintain a vacuum state.

The structure of the semiconductor manufacturing apparatus 200 may be an example of a manufacturing apparatus including the substrate support apparatus 100, but the embodiments are not limited thereto. The semiconductor manufacturing apparatus 200 may be any of various semiconductor manufacturing apparatuses, such as a deposition apparatus or the like, and may include the substrate support apparatus 100 according to an embodiment.

FIG. 6 illustrates an example of a semiconductor manufacturing apparatus 300 that includes the substrate support apparatus 100 illustrated in FIG. 1.

Referring to FIG. 6, a semiconductor manufacturing apparatus 300 according to an embodiment may be a test apparatus. For example, the semiconductor manufacturing apparatus 300 may include a chamber 310, a laser supply 320, an optical system 330, and a substrate support apparatus 100.

The chamber 310 may provide a space in which the substrate support apparatus 100 and the optical system 330 are disposed. The laser supply 320 may supply laser, and the optical system 330 may test or inspect a substrate 110 through using the laser incident from the laser supply 320.

The semiconductor manufacturing apparatus 300 may be an example of a manufacturing apparatus that may not necessarily require the chamber to be in a vacuum state during operation. The invention is not limited to the test apparatus. The semiconductor manufacturing apparatus 300 may be any of various non-vacuum manufacturing apparatuses, such as a cleaning apparatus, a deposition apparatus, or the like, and may include the substrate support apparatus 100 according to an embodiment.

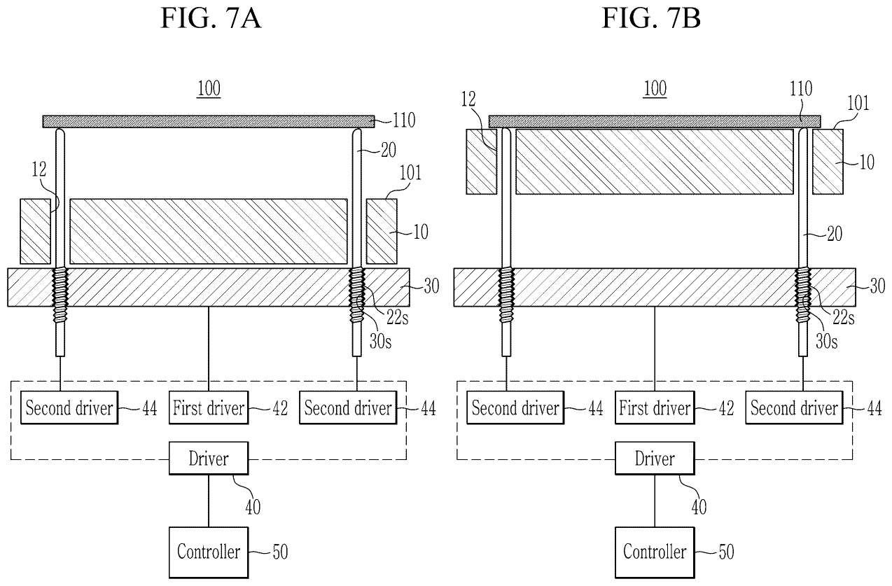

Referring to FIG. 7A to FIG. 10, an operation method of a substrate support apparatus 100 according to an embodiment will be described in detail.

FIG. 7A and FIG. 7B conceptually illustrate an operation method of a substrate support apparatus 100 according to an embodiment. FIG. 7A and FIG. 7B illustrate relative positions of a chuck 10 and a lift pin 20.

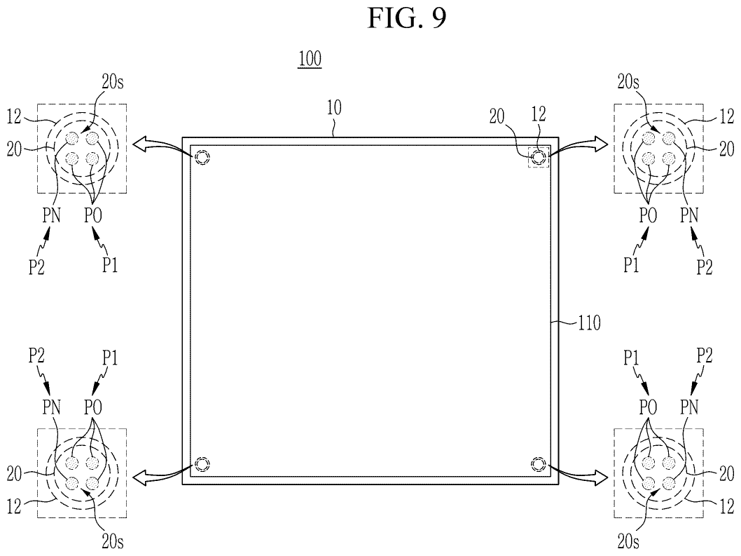

Referring to FIG. 7A and FIG. 7B, an operation method of a substrate support apparatus 100 according to an embodiment may include a mounting step and a separating step. In the mounting step, a substrate 110 may be disposed on a support portion 20s (refer to FIG. 3) of a lift pin 20 and the substrate 110 may be mounted on the chuck 10. For example, the mounting step may include disposing the substrate 110 on a support portion 20s (referring to FIG. 3) of a lift pin 20. Subsequently, the substrate 110 may be mounted on and/or in contact with the chuck 10. In the separating step, the substrate 110 may be separated (or detached) from the chuck 10. In an embodiment, the mounting step may include a planar-position control process where a planar position of the support portion 20s of the lift pin 20 may be changed from a first support position P1 (refer to FIGS. 8 and 9) to a second support position P2 (refer to FIGS. 8 and 9).

In the mounting step, as illustrated in FIG. 7A, the substrate 110 may be disposed on the lift pin 20 in a protruded state. In the protruded state, the lift pin 20 may protrude above (beyond) the chuck 10. For example, the lift pin 20 may be disposed at an upper position so that an upper portion of the lift pin 20 is higher than a first surface 101 of the chuck 10, and the substrate 110 may be disposed on the lift pin 20. For example, the lift pin 20 may support the substrate 110 in a state that the support portion 20s of the lift pin 20 is adjacent to (or in contact with) a lower surface of the substrate 110. The vertical position of the lift pin 20 may be changed using a driver 40 (e.g., a first driver 42) to a non-protruded state, as illustrated in FIG. 7B. In the non-protruded state, the lift pin 20 may not protrude above the chuck 10. For example, the lift pin 20 may be at a lower position in which the upper portion of the lift pin 20 is disposed at the same level or lower than the first surface 101 of the chuck 10. Thereby, the substrate 110 may be mounted on the first surface 101 of the chuck 10. In this state, the substrate 110 may be in contact with and secured to the chuck 10 using an electrostatic force.

In an embodiment, before or in a process of disposing the substrate 110 on the lift pin 20, the planar-position control process (process of changing the planar position of the support portion 20s of the lift pin 20, e.g., from the first support position P1 to the second support position P2) may be performed. For example, in an embodiment, before or in the process of disposing the substrate 110 on the lift pin 20, the planar position of the support portion 20s of the lift pin 20 that supports the lower surface of the substrate 110 may be changed from the first support position P1 to the second support position P2.

The phrase that the planar-position control process is performed before the process of disposing the substrate 110 on the lift pin 20 may include a case in which the planar-position control process is performed just before the process of disposing the substrate 110 on the lift pin 20 and a case in which the planar-position control process is performed after a preceding process (e.g., after a separating step in the preceding process). For example, the planal position of the support portion 20s may be changed right, before the substrate 110 is in contact with the lift pin 20. In an example, the planal position of the support portion 20s may be changed right after the substrate 110 is detached from the chuck 10 by the driver 40.

The planar-position control process may be performed by rotating the lift pin 20 using a driver 40 (e.g., a second driver 44). Because the support portion 20s of the lift pin 20 may be spaced apart from a center of the lift pin 20, the planar position of the support portion 20s of the lift pin 20 may be readily changed by the rotation of the lift pin 20.

Examples of changing the planar position of the support portion 20s of the lift pin 20 in the planar-position control process will be described later in detail with reference to FIG. 8 and FIG. 9.

In the separating step, the substrate 110 may be released from the chuck 10 in the non-protruded state as illustrated in FIG. 7B, and the vertical position of the lift pin 20 may be changed using the driver 40 (e.g., the first driver 42) to the protruded state (in which the lift pin 20 protrudes above the chuck 10, as illustrated in FIG. 7A) from the non-protruded state. Thereby, the substrate 110 may be separated from the first surface 101 of the chuck 10.

The substrate 110 may be processed after the mounting step. After the substrate processing, the separating step may be performed. For example, the mounting step in which the substrate 110 is mounted on the chuck 10 may be performed before a unit manufacturing process in a semiconductor manufacturing apparatus, and the separating step in which the substrate 110 is separated from the chuck 10 may be performed after the unit manufacturing process in the semiconductor manufacturing apparatus. The unit manufacturing process may be performed in a semiconductor manufacturing apparatus that performs at least one process of a plurality of processes included in a manufacturing process of a semiconductor device. For example, the unit manufacturing apparatus may be an etching apparatus, a deposition apparatus, a cleaning apparatus, an exposure apparatus, a developing apparatus, a test apparatus, or the like, and the unit manufacturing process may be an etching process, a deposition process, a cleaning process, an exposure process, a developing process, a test process, or the like.

For example, in the semiconductor manufacturing apparatus 200 illustrated in FIG. 5, the substrate 110 may be disposed on the lift pin 20 in the protruded state, the substrate 110 may be mounted on the chuck 10 of the substrate support apparatus 100 by changing the vertical position of the lift pin 20, and the substrate 110 may be in contact with and secured to the chuck 10 using an electrostatic force. While the substrate 110 is secured, the unit manufacturing process by the semiconductor manufacturing apparatus 200 may be performed. For example, an etching process may be performed using plasma and a reaction gas. When the unit manufacturing process (e.g., etching process) is completed, the vertical position of the lift pin 20 may be changed from the non-protruded state to the protruded state to cause the substrate 110 is released from the chuck 10. Accordingly, the substrate 110 may be separated from the chuck 10.

For example, in the semiconductor manufacturing apparatus 300 illustrated in FIG. 6, the substrate 110 may be disposed on the lift pin 20 of the protruded state. Subsequently, the substrate 110 may be mounted on the chuck 10 of the substrate support apparatus 100 by changing the vertical position of the lift pin 20 such that the substrate 110 may be in contact with and fixed or secured to the chuck 10 using an electrostatic force. While the substrate 110 is fixed, the unit manufacturing process by the semiconductor manufacturing apparatus 300 may be performed. For example, a test process of the unit manufacturing process may be performed using the laser supply 320 and the optical system 330. When the unit manufacturing process is completed, the substrate 110 may be released from the chuck 10, and the vertical position of the lift pin 20 may be changed from the non-protruded state to the protruded state. Accordingly, the substrate 110 may be separated from the chuck of the substrate support apparatus 100.

Examples of changing a planar position of a support portion 20s of a lift pin 20 in the planar-position control process will be described in detail with reference to FIG. 8 and FIG. 9.

FIG. 8 illustrates an example of changing a planar position of a support portion 20s of a lift pin 20 in an operation method of a substrate support apparatus 100 according to an embodiment.

Referring to FIG. 8, in a planar-position control process according to an embodiment, a planar position of a support portion 20s of a lift pin 20 may be switched between a first support position P1 and a second support position P2. For example, the planar position of the support portion 20s may be changed to be adjacent to an edge or an outer side of a substrate 110 or a chuck 10. Accordingly, the planar position may change from first support position P1 to second support position P2. For example, the second support position P2 of the lift pin 20 (planar position after the planar-position control process) may be adjacent to the edge or the outer side of the substrate 110 or the chuck 10 as compared to the first support position P1 of the lift pin 20 (planar position before the planar-position control process).

Thereby, in a state that the support portion 20s is positioned adjacent to the edge or the outer side of the substrate 110 or the chuck 10, the lift pin 20 may support a lower surface of the substrate 110. Accordingly, a region of the substrate 110 in which contamination or damage may be induced by the lift pin 20 may be reduced and an area of an inner region of the substrate 110 in which the lift pin 20 is not adjacent to (e.g., in contact with) may increase. By changing a structure of the lift pin 20, a substrate support apparatus 100 may be easily applied in a case or the like where an area of an inspection region of the substrate 110 is increased. In the inspection region, inspection for contamination or damage of the substrate 110 may be performed. Accordingly, without changing an equipment (e.g., a chamber or a chuck) other than the lift pin 20, the substrate support apparatus 100 may be easily applied in the case or the like where the area of the inspection region of the substrate 110 is increased. For example, when the substrate 100 is repeatedly positioned on the chuck 10, mechanical contact between the support portion 20s and the substrate 100 may occur in a plurality of planar positions (e.g., P1 and P2) by the position switching of the support portion 20s. Accordingly, a certain region (corresponding to one of P1 and P2) of the substrate 110 may be less susceptible to contamination or damage induced by the lift pin 20, and the substrate support apparatus 100 may be utilized (or processed) with increased reliability and durability.

FIG. 9 illustrates an example of changing a planar position of a support portion 20s of a lift pin 20 in an operation method of a substrate support apparatus 100 according to an embodiment. FIG. 10 conceptually illustrates an operation method of a plurality of substrate support apparatuses 100 included in a plurality of semiconductor manufacturing apparatuses 400a and 400b.

For a clear understanding, FIG. 10 illustrates a controller 50 of a substrate support apparatus 100 at an outside of first and second semiconductor manufacturing apparatuses 400a and 400b.

Referring to FIG. 9, in a planar-position control process according to an embodiment, a planar position of a support portion 20s of a lift pin 20 may be changed to a non-overlapping position (or target position) PN. The non-overlapping position PN may be a position other than a support position (i.e., a preceding support position PO) used in a preceding process. The preceding process may refer to one or a plurality of manufacturing processes (e.g. unit manufacturing processes) performed before a target manufacturing process (ongoing or present process) to be currently in execution or underway. In the target manufacturing process, the substrate 110 is supported by one or a plurality of substrate support apparatuses 100.

For example, in the planar-position control process, the planar position of the support portion 20s of the lift pin 20 may be changed from one of the preceding support positions PO (e.g., first support positions P1 as illustrated in the drawing) to the non-overlapping position PN (second support position P2). In FIG. 9 and the related description, it is illustrated and described as an example that there are a plurality of preceding support positions PO, but the embodiments are not limited thereto.

For example, the preceding process of one unit manufacturing process may refer to one or a plurality of manufacturing processes (e.g. unit manufacturing processes) performed before the one unit manufacturing process in a same semiconductor manufacturing apparatus. Thereby, in a plurality of unit manufacturing processes performed in a same semiconductor manufacturing apparatus, support positions of the substrate 110 supported by the support portion 20s of the lift pin 20 may be different. In an embodiment, the preceding process and the target process may be different process steps in a series of semiconductor manufacturing processes. For example, the preceding process may be configured to be performed before the target process. For example, during the series of semiconductor manufacturing processes, a plurality of unit steps may be performed on a substrate 110 in the same manufacturing apparatus, and a position at which the substrate 110 is supported by the support portion 20s in one of the process steps may be adjusted to be different from those of other proceeding steps.

In some embodiments, the preceding process of one unit manufacturing process may refer to one or a plurality of manufacturing processes (e.g. unit manufacturing processes) performed before the one unit manufacturing process in a semiconductor manufacturing apparatus different from a semiconductor manufacturing apparatus where the one unit manufacturing process is performed. For example, the preceding process and the target process may be a different process step in a series of semiconductor manufacturing processes. For example, the preceding process may be performed before the target process. The preceding process and the target process may be performed in different manufacturing apparatuses 400a and 400b. For example, as illustrated in FIG. 10, a support portion 20s of a lift pin 20 may support a substrate 110 in a first support position P1 in a first semiconductor manufacturing apparatus 400a, and a support portion 20s of a lift pin 20 may support the substrate 110 in a second support position P2 in a second semiconductor manufacturing apparatus 400b. Thereby, in a plurality of unit manufacturing processes performed in different semiconductor manufacturing apparatuses, support positions of the substrate 110 supported by the support portions 20s of the lift pins 20 may be different. In FIG. 10, it is illustrated as an example that an integrated controller 500 configured to control a plurality of controllers 50 controlling a plurality of substrate support apparatuses 100 is provided, but the embodiments are not limited thereto. For example, two controllers 50 may control two substrate support apparatuses 100, respectively. One controller 50 may control a plurality of substrate support apparatuses 100 included in a plurality of semiconductor manufacturing apparatuses.

In an embodiment, in a plurality of unit manufacturing processes, the lift pin 20 (or the lift pins 20) may be rotated by a predetermined angle (e.g., 1 degree or more, and less than 360) to support the substrate 110. The support portions in the first semiconductor manufacturing apparatus 400a may be different from the support portions in the second semiconductor manufacturing apparatus 400b. For example, the first and second semiconductor manufacturing apparatuses 400a and 400b may be used in the same step of a series of semiconductor manufacturing processes. Accordingly, it may be usefully applied in a case where a large number of unit manufacturing processes are included. However, the embodiments are not limited thereto, and rotation angles of the lift pin 20 (or the lift pins 20) in a plurality of unit manufacturing processes may be different from each other. The lift pin 20 (or the lift pins 20) may be rotated by any of other various methods.

Thereby, in the plurality of unit manufacturing processes, the supported positions of the substrate 110 by the support portion 20s of the lift pin 20 may be different. Accordingly, damage (a scratch, a crack, or the like) or contamination of a substrate that may be induced when the substrate is repeatedly supported in the same position may be prevented or reduced. For example, according to an embodiment, when the substrate 110 may include a glass substrate and/or may be easily breakable if repeatedly contact in the same position (e.g., when the substrate 110 may be a glass substrate), the breakage of the substrate 110 may be prevented.

According to embodiment, by changing the planar position of the support portion 20s of the lift pin 20 that supports the substrate 110, the contamination or damage of the substrate 110 due to the lift pin 20 may be minimized. Thereby, a defect of the substrate 110 may be reduced and performance and productivity of a semiconductor device that includes the substrate 110 or is formed by using the substrate 110 may be enhanced. By changing a shape or a structure of the lift pin without changing a structure of a chuck or a semiconductor manufacturing apparatus, the planar position of the support portion 20s of the lift pin 20 may be easily changed or controlled.

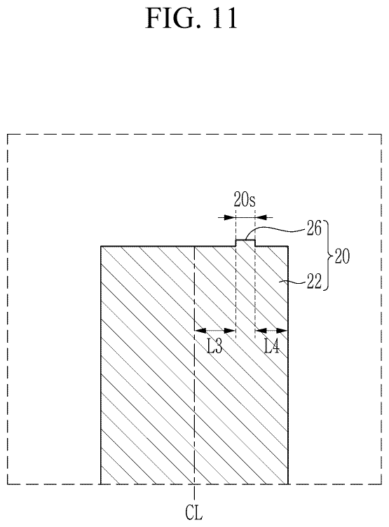

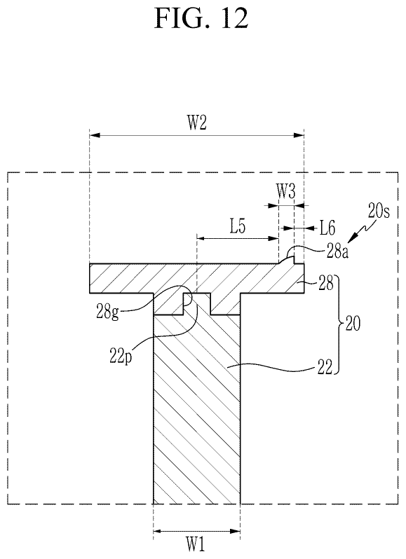

Hereinafter, referring to FIG. 11 and FIG. 12, substrate support apparatuses according to embodiments will be described in detail. To the extent that an element is not described in detail below, it may be understood that the element is at least substantially similar to a corresponding element that has been described elsewhere within the present disclosure. A portion which is not described in the above may be described in detail.

FIG. 11 is a cross-sectional view that illustrates a portion of a substrate support apparatus according to an embodiment. FIG. 11 illustrates a potion corresponding to FIG. 3.

Referring to FIG. 11, in an embodiment, a lift pin 20 may include a main body 22, and a protruding portion 26 that is disposed at an upper portion of the main body 22. A support portion 20s of the lift pin 20 may be a portion (e.g., an uppermost portion) of the protruding portion 26.

The main body 22 may extend in a vertical direction (a Z-axis direction in the drawings) to pass through a pin hole 12. The main body 22 may have substantially the same area except for a portion configured to be connected to a driver. For example, the main body 22 may have a column shape. In the drawings, it is illustrated as an example that the main body 22 has a circular cylinder shape. However, the embodiments are not limited thereto, and a shape of the main body 22 may be variously modified.

The protruding portion 26 may be disposed at the upper portion of the main body 22 and have an area less than an area of the main body 22. For example, an upper surface of the protruding portion 26 may constitute or be the support portion 20s. In FIG. 11, it is illustrated as an example that the upper surface of the protruding portion 26 may have a flat surface, but the embodiments are not limited thereto. The upper surface of the protruding portion 26 may be a rounded surface or a curved surface. Other various modified embodiments are possible.

The support portion 20s may be offset from the center axis CL extending along the lengthwise direction of the lift pin 20 (or the main body 22). In an embodiment, in a plan view, the support portion 20s (e.g., the protruding portion 26) of the lift pin 20 may be spaced apart from a center of the lift pin 20.

In an embodiment, the protruding portion 26 may be disposed in the main body 22 in a plan view. For example, in a plan view, a third distance L3 may be greater than a fourth distance L4. The third distance L3 may be a shortest distance between the protruding portion 26 and the center of the lift pin 20 (e.g., the center axis CL of the main body 22) or between the support portion 20s of the lift pin 20 and the center of the lift pin 20 (e.g., the center axis CL of the main body 22) in a horizontal plane. The fourth distance L4 may be a shortest distance between the protruding portion 26 and an edge of the lift pin 20 (e.g., an edge of the main body 22) or between the support portion 20s of the lift pin 20 and the edge of the lift pin 20 (e.g., the edge of the main body 22) in the horizontal plane. Thereby, by the rotation of the lift pin 20, a planar position of the support portion 20s of the lift pin 20 may be changed more easily. However, the embodiment is not limited thereto. In some embodiments, the third distance L3 between the support portion 20s of the lift pin 20 and the center of the lift pin 20 may be the same as or less than the fourth distance L4 between the support portion 20s of the lift pin 20 and the edge of the lift pin 20.

For example, the area of the footprint of the protruding portion 26 may have a value in the range of 10% to 30% of the area of the footprint of the lift pin 20. However, the embodiments are not limited thereto, and the area of the footprint of the protruding portion 26 may be less than 10% or greater than 30% of the area of the footprint of the lift pin 20.

By rotating the lift pin 20 clockwise or counterclockwise in a plan view, the planar position of the support portion 20s may be changed. During the rotation, the planar position of the support portion 20s may follow a trajectory, and the maximum distance between two points on the trajectory may be a maximum position deviation of the support portion 20s. The maximum position deviation of the protruding portion 26 or the support portion 20s by the rotation of the lift pin 20 may be in a range of 0.2 mm to 3 mm. However, the embodiments are not limited thereto, and the maximum position deviation of the protruding portion 26 or the support portion 20s by the rotation of the lift pin 20 may be less than 0.2 mm or greater than 3 mm.

In an embodiment, the lift pin 20 that includes the main body 22 and the protruding portion 26 may be formed of a single continuous body to have an integral structure. Through processing the upper portion of the lift pin 20, the protruding portion 26 (or the support portion 20s) may be formed to have the offset configuration. However, the embodiments are not limited thereto, and a portion that includes the protruding portion 26 may be separately formed from (and/or be coupled to) the main body 22 and be fixed to the main body 22 to form the lift pin 20. The portion that includes the protruding portion 26 may be removably or detachably fixed (coupled) to the main body 22, or may be fixed to the main body 22 in a non-separable or non-detachable manner. Other various modified embodiments are possible.

FIG. 12 is a cross-sectional view that illustrates a portion of a substrate support apparatus according to an embodiment. FIG. 12 illustrates a potion corresponding to FIG. 3.

referring to FIG. 12, in an embodiment, a lift pin 20 may include a main body (or main body portion) 22, and an upper cap (or upper body portion) 28 that is disposed at an upper portion of the main body 22. A support portion 20s that is disposed at an upper portion of the upper cap 28 may be in contact with a lower surface of a substrate and support the substrate. The support portion 20s of the lift pin 20 may be a portion of the upper cap 28. For example, the support portion 20s of the lift pin 20 may be an uppermost portion (or a protruding part 28a) of the upper cap 28.

The main body 22 may extend in a vertical direction (a Z-axis direction in the drawings) to pass through a pin hole 12. The main body 22 may have substantially the same area except for a portion (e.g., an upper portion including an insertion groove 28g) configured to be fixed to the upper cap 28 and a portion configured to be connected to a driver. For example, the main body 22 may have a column shape. In the drawings, it is illustrated as an example that the main body 22 has a circular cylinder shape. However, the embodiments are not limited thereto, and a shape of the main body 22 may be variously modified.

The upper cap 28 may be disposed at the upper portion of the main body 22. For example, a lower surface of the upper cap 28 may be provided with an insertion groove 28g to which a portion (e.g., a fixed part 22p) of the main body 22 is inserted. The portion (e.g., the fixed part 22p) of the main body 22 may be inserted to the insertion groove 28g of the upper cap 28 so that the main body 22 and the upper cap 28 are fixed to each other. For example, the upper cap 28 may be removable or detachable from the main body 22. However, the embodiments are not limited thereto, and the upper cap 28 may be fixed to the main body 22 in a non-separable or non-detachable manner. In some embodiments, the lift pin 20 may be an integral body (or a single body or a continuous body) including the main body 22 and the upper cap 28.

In a direction parallel to the chuck 10, a width W2 of the upper body portion 28 is greater than a maximum width W1 of the main body in a cross-sectional view. For example, a width W2 of the upper cap 28 may be greater than a width W1 of the main body 22. The width W1 of the main body 22 may refer to a maximum width (e.g., a long width or a maximum diameter) in a cross-sectional view, and the width W2 of the upper cap 28 may refer to a maximum width (e.g., a long width or a maximum diameter) in a cross-sectional view. For example, a ratio (W2/W1) of the width W2 of the upper cap 28 to the width W1 of the main body 22 may be 2 or more (e.g., 3 or more), and may be 20 or less (e.g., 10 or less). When the ratio (W2/W1) of the width W2 of the upper cap 28 to the width W1 of the main body 22 is 2 or more (e.g., 3 or more), the support portion 20s of the lift pin 20 may be disposed far away from a center of the lift pin 20 and a planar position of the lift pin 20 may be changed more easily. However, the embodiments are not limited thereto, and the ratio (W2/W1) of the width W2 of the upper cap 28 to the width W1 of the main body 22 may be less than 2 or greater than 20.

An upper surface of the upper cap 28 may be provided with the protruding part 28a that protrudes to be adjacent to the substrate.

In a cross-sectional view, a width W3 of the protruding part 28a of the upper cap 28 may be less than the width W1 of the main body 22. The width W3 of the protruding part 28a of the upper cap 28 may refer to a maximum width (e.g., a long width or a maximum diameter) in a cross-sectional view.

The support portion 20s may be offset from the center axis of the main body 22. In an embodiment, in a cross-sectional view, the support portion 20s (e.g., the protruding part 28a of the upper cap 28) of the lift pin 20 may be spaced apart from the center of the lift pin 20.

In an embodiment, the protruding part 28a of the upper cap 28 may be disposed outside the main body 22 in a cross-sectional view. For example, in a plan view, a fifth distance L5 may be greater than a sixth distance L6. The fifth distance L5 may be a distance between the protruding part 28a of the upper cap 28 and the center of the lift pin 20 (e.g., a center of the main body 22) in a cross-sectional view. The sixth distance L6 may be a shortest distance between the protruding part 28a of the upper cap 28 and an edge of the lift pin 20 (e.g., an edge of the upper cap 28). Thereby, by the rotation of the lift pin 20, the planar position of the support portion 20s of the lift pin 20 may be changed more easily. However, the embodiment is not limited thereto. In some embodiments, the fifth distance L5 may be the same as or less than the sixth distance L6.

In an embodiment, an area of the protruding part 28a of the upper cap 28 may be less than an area of the main body 22, and an area of the support portion 20s that is adjacent to (or in contact with) the lower surface of the substrate may be reduced. Thereby, damage or contamination of the substrate that may be induced in a support position of the lift pin 20 may be reduced.

For example, in a plan view, the area of the footprint of the protruding part 28 a of the upper cap 28 may have a value in the range of 10% to 30% of the area of the footprint of the main body 22. However, the embodiments are not limited thereto, and the area of the footprint of the protruding part 28a of the upper cap 28 may be less than 10% or greater than 30% of the area of the footprint of the main body 22.

The lift pin 20 (e.g., the main body 22 and/or the upper cap 28) may include or be formed of any of various materials, such as metal, a carbon-based material, a fiber-reinforced resin, or the like. The upper cap 28 also may include or be formed of such materials (the same material as that of the main body 22) to enhance structural stability. However, the embodiments are not limited thereto, and the upper cap 28 may include or be formed of a material different from a material of the main body 22.

In an embodiment, before or in a process of disposing of the substrate on the lift pin 20, a planar-position control process to change a planar position of the support portion 20s of the lift pin 20 may be performed. The planar-position control process may be performed by rotating the lift pin 20 using a driver (e.g., a second driver). The support portion 20s of the lift pin 20 may be spaced apart from the center of the lift pin 20, and the planar position of the support portion 20s (i.e., the protruding part 28a of the upper cap 28) of the lift pin 20 may be easily changed by the rotation of the lift pin 20.

For example, as illustrated in FIG. 8, in the planar-position control process, by rotating the lift pin 20, the planar position of the support portion 20s (i.e., the protruding part 28a of the upper cap 28) of the lift pin 20 may be changed to be adjacent to an edge or an outer side of the substrate 110 or a chuck 10. For example, as illustrated in FIG. 9, in the planar-position control process according to an embodiment, the planar position of the support portion 20s (i.e., the protruding part 28a of the upper cap 28) of the lift pin 20 may be changed to a non-overlapping position. The non-overlapping position may be a position other than a support position (i.e., a preceding support position) of the substrate 110 in a preceding process.

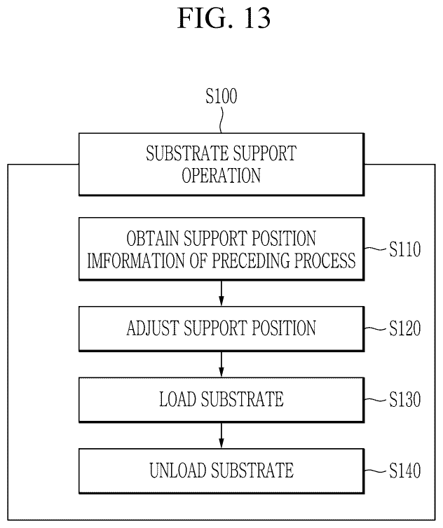

A method of manufacturing a semiconductor device may include a series of process steps. For example, the method of manufacturing the semiconductor device may include processing a substrate that is supported by a substrate support apparatus. In at least of the process steps, a substrate support operation may be performed. FIG. 13 illustrates a substrate support operation S100 according to an embodiment. The descriptions in conjunction with drawings discussed above may be applicable as embodiments of the substrate support operation S100.

Referring to FIG. 13 and other drawings discussed above, the substrate support apparatus 100 may include a lift pin 20 and a chuck 10. For example, a support portion 20s of the lift pin 20 may be positioned in a first support position (planar position) at the initial stage of the operation S100.

In an operation S110, a support position information of a preceding process (or a plurality of processes) may be obtained. For example, the store support position information may include the history of the substrate 110 to be positioned on the chuck 10. The history of the substrate 110 may be as to which areas have had mechanical contact with specific production apparatus (or apparatuses), how many mechanical contacts were made in such areas of the substrate 110, and so on.

The support position information may also include information on the semiconductor manufacturing apparatus (or the substrate support apparatus 100) in which the substrate 110 is to be loaded. For example, the support position information may be as to how many times the support portion 20s has been in contact with the substrate 110 (and/or other substrates) in each specific planar position. In addition, the support position information may further include information on target position information. The target position information may be on a target position (where the support portion 20s is located in a target manufacturing process to be currently in execution or underway).

In an operation S120, the lift pin 20 may be adjusted to change the planar position of the support portion 20s of the lift pin 20 from the first support position to a second support position different from the first support position. The second support position may be the target position.

In an operation S130, the substrate 110 may be loaded in the substrate support apparatus 100 and mounted on the chuck 10, while the planar position of the support portion 20s of the lift pin 20 is in the second support position.

In an operation S140, the substrate 110 may be unloaded from the substrate support apparatus 100, while the planar position of the support portion 20s of the lift pin 20 is in the second support position.

While some examples have been described in connection with what is presently considered to be some practical embodiments, it is to be understood that the invention is not limited to the disclosed embodiments, and that the disclosure is intended to cover various modifications and equivalent arrangements included within the spirit and scope of the appended claims.

What is claimed is:

1. A substrate support apparatus, comprising:
a chuck configured to mount a substrate thereon; and
a lift pin that passes through the chuck, the lift pin having a support portion that is configured to support a lower surface of the substrate,
wherein the support portion of the lift pin is spaced apart from a center of the lift pin in a plan view.

2. The substrate support apparatus of claim 1, further comprising:
an actuator configured to rotate the lift pin to change a horizontal position of the support portion of the lift pin,

3. The substrate support apparatus of claim 1, wherein the lift pin is configured to be rotated so that the horizontal position of the support portion of the lift pin changes from a first support position in a first horizontal plane to a second support position in the first horizontal plane.

4. The substrate support apparatus of claim 1, wherein the lift pin is configured to be adjusted such that the horizontal position of the support portion of the lift pin is changed to be between the center of the lift pin and an edge of the substrate or the chuck in a plan view.

5. The substrate support apparatus of claim 1, further comprising:
an actuator configured to rotate the lift pin to change a horizontal position of the support portion of the lift pin; and
a controller configured to control the actuator,
wherein the controller comprises a processor and storage, the storage is configured to store support position information including lift pin support positions indicating locations on the substrate where the lift pin has contacted the substrate to support the substrate,
wherein the actuator is configured to move the lift pin, and
wherein the controller is configured to modify a support position of the lift pin from a first support position to a second support position based on the lift pin support positions stored in the storage.

6. The substrate support apparatus of claim 1,
wherein the lift pin includes a main body and a protruding portion that extends from an upper portion of the main body,
wherein the protruding portion has a footprint having an area less than an area of a footprint of the main body, or the protruding portion has an asymmetrical shape with respect to a vertical line passing through a center of the main body with respect to a vertical cross section, and
wherein the support portion of the lift pin forms a top end of the protruding portion.

7. The substrate support apparatus of claim 6,
wherein the main body and the protruding portion constitute a continuous body, or
wherein the protruding portion is detachable from the main body.

8. The substrate support apparatus of claim 1,
wherein the lift pin includes a main body and a cap that is at an upper portion of the main body, and
wherein the support portion of the lift pin is part of the cap.

9. The substrate support apparatus of claim 8,
wherein the support portion is formed as a protruding part extending from a main upper surface of the cap and has a footprint having an area less than an area of a footprint of the main body, and
wherein, with respect to a plan view, the protruding part locates outside of the footprint of the main body.

10. The substrate support apparatus of claim 8, wherein, in a direction parallel to an upper surface of the chuck, a width of the cap is greater than a width of the main body.

11. The substrate support apparatus of claim 8, wherein the cap is removably attached to the upper portion of the main body.

12. The substrate support apparatus of claim 8, wherein the cap is formed of the same material as that of the main body.

13. A substrate support apparatus, comprising:
a chuck configured to mount a substrate thereon; and
a lift pin that passes through the chuck and configured to support the substrate, wherein the lift pin includes a support portion configured to contact the substrate, and the support portion is at an upper portion of the lift pin, and
wherein the lift pin is configured to be rotated and support the substrate in a first support position or a second support position different from each other in a plan view.

14. The substrate support apparatus of claim 13, further comprising an actuator configured to rotate the lift pin to change a horizontal position of the support portion of the lift pin,
wherein the support portion of the lift pin is spaced apart from a center of the lift pin in a plan view.

15. The substrate support apparatus of claim 13, wherein the support portion of the lift pin is configured to support a lower surface of the substrate while the support portion of the lift pin is between a center of the lift pin and an edge of the chuck in a plan view.

16. The substrate support apparatus of claim 13, further comprising a controller configured to control the lift pin to be rotated,
wherein the controller comprises a processor and storage, the storage is configured to store support position information including lift pin support positions indicating locations on the substrate where the lift pin has contacted the substrate to support the substrate, and
wherein the controller is configured to modify a support position of the lift pin from a first support position to a second support position based on the lift pin support positions stored in the storage.

17. An operation method of a substrate support apparatus, comprising:
providing the substrate support apparatus including a lift pin and a chuck, wherein a horizontal position of a support portion of the lift pin is a first support position;
adjusting the lift pin to change the horizontal position of the support portion of the lift pin from the first support position to a second support position, wherein the second support position is different from the first support position;
mounting a substrate on the chuck, while the horizontal position of the support portion of the lift pin is in the second support position; and
separating the substrate from the chuck while the horizontal position of the support portion of the lift pin is in the second support position.

18. The operation method of claim 17, wherein the support portion of the lift pin supports a lower surface of the substrate,
wherein the support portion of the lift pin is spaced apart from a center of the lift pin in a plan view, and
wherein, the substrate support apparatus is configured to rotate the lift pin to change the horizontal position of the support portion of the lift pin.

19. The operation method of claim 17, wherein, the substrate support apparatus is configured to change the horizontal position of the support portion of the lift pin to be between a center of the lift pin and an edge of the chuck in a plan view.

20. The operation method of claim 17, wherein, in the first support position, a mechanical contact with the substrate has occurred in a preceding process, and wherein, in the second support position, a mechanical contact with the substrate has not occurred in the preceding process.
